(19) United States
(12) Patent Application Publication
(10) Pub. No.: US 2006/0291308 A1
(43) Pub. Date: Dec. 28, 2006

(54) Test method and test program for semiconductor storage device, and semiconductor storage device

(76) Inventor: Isao Yusa, Kurokawa-gun (JP)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/403,394

(22) Filed: Apr. 13, 2006

(30) Foreign Application Priority Data
Jun. 15, 2005 (JP) 2005-174739

(51) Int. Cl. G11C 29/00

(52) U.S. Cl. 365/201

(57) ABSTRACT

A method and program for testing a semiconductor storage device enabling efficient determination of memory cells that may cause disturbance. The semiconductor storage device includes a memory cell array including an array of memory cells, an X decoder for applying predetermined voltage to the gate terminals of the memory cells, a Y decoder for applying predetermined voltage to the source and drain terminals of the memory cells, and a BIST module for providing a signal to the X and Y decoders to test the device. The BIST module writes data of “1” to each of the memory cells before applying pulse voltage, which has a duration substantially equal to read time of the memory cells, at the same time for a predetermined period. Memory cell that may cause disturbance are determined by identifying memory cells in which the data changes after the voltage application.

### BACKGROUND OF THE INVENTION

The present invention relates to a test method, a test program, and a semiconductor storage device for a semiconductor storage device such as a non-volatile memory.

In recent years, semiconductor storage devices that store data are used for various applications. Such a semiconductor storage device undergoes inspections so that defective products are not sent out of the manufacturing factory. One of such inspections is a burn-in test. The burn-in test is conducted by applying voltage to a semiconductor storage device in an environment in which stress is added to the semiconductor storage device under a high temperature (e.g. 125° C.) to locate initial defects of the semiconductor storage device.

For a semiconductor storage device (memory) including a matrix of memory cells, data is deleted from and written to a cell selected by a bit line and a word line. However, when repeating the deletion and writing of data, the application of bias voltage to a cell other than the selected cell causes electronic tunneling, which may result in electron transfer between the source-drain and the floating gate of the memory cell. This may lead to data disturbance that would change the threshold voltage Vt and rewrite data. A disturb stress test is conducted to determine whether such phenomenon would lead to a deficiency.

The disturb stress test, which is conducted on a device provided with a test mode for enabling external control of voltage applied to a bit line and a word line, evaluates changes in data by controlling the applied voltage. A method for testing a non-volatile semiconductor memory that tests and evaluates a semiconductor memory to accurately obtain the disturbance amount and disturb margin within a short period of time has been proposed. The invention described in Japanese Patent Laid-Open Publication No. 2002-56698 describes a disturb stress application process in which a sequence of stepped pulses are applied to each word line. Then, the threshold of the memory cell disturbed most in each word line is measured, and the difference between this threshold and the threshold of a data read limit when deleting data is obtained as a disturb margin. A product having a disturb margin greater than a satisfactory determination value is determined to be non-defective.

In the invention described in Japanese Patent Laid-Open Publication No. 2002-56698, the possibility of data disturbance occurring in a memory cell is checked based on the threshold of a memory cell in which data has changed due to disturb stress to locate defective semiconductor storage devices. However, in this test method, since a sequence of stepped pulses are applied to each word line, the determination of defective products in which data disturbance occurs is not performed in an efficient manner. Additionally, the pulse width and number of times for applying pulses are determined based on the time period required for performing normal writing. Thus, there is a limit to screening defective products.

### SUMMARY OF THE INVENTION

It is an object of the present invention to provide a test method and a test program for a semiconductor storage device, and a semiconductor storage device enabling efficient determination of memory cells in which there is a possibility of data disturbance occurring and efficient determination of whether or not a product is defective.

One aspect of the present invention is a method for testing a semiconductor storage device including a plurality of memory cells. The method includes the steps of applying to predetermined terminals of the memory cells pulse voltage, which has a duration equal to or close to data read time of the memory cells, at the same time for a predetermined time period, reading data from the memory cells after the application of the pulse voltage to compare the read data with initial data of the memory cells before the application of the pulse voltage, and determining a memory cell in which the initial data before the application of the pulse voltage differs from the read data after the application of the pulse voltage as being a memory cell that would cause disturbance.

Another aspect of the present invention is a test program for testing a semiconductor storage device including a plurality of memory cells. The test program has a computer function as a means for applying to predetermined terminals of the memory cells pulse voltage, which has a duration equal to or close to data read time of the memory cells, at the same time for a predetermined time period, a means for reading data from the memory cells after the application of the pulse voltage to compare the read data with initial data of the memory cells before the application of the pulse voltage, and determining a memory cell in which the data before the application of the pulse voltage differs from the read data after the application of the pulse voltage as being a memory cell that would cause disturbance.

A further aspect of the present invention is a semiconductor storage device including a plurality of memory cells. The semiconductor device includes a test executing means for supplying voltage and providing a signal to the memory cells to perform an operation check on the memory cells. The test executing means selects terminals of the memory cells to which voltage is to be applied and applies to the selected terminals pulse voltage, which has a duration equal to or close to data read time of the memory cells, at the same time for a predetermined time period.

Other aspects and advantages of the present invention will become apparent from the following description, taken in conjunction with the accompanying drawings, illustrating by way of example the principles of the invention.

### BRIEF DESCRIPTION OF THE DRAWINGS

FIG. 1 is a graph illustrating the relationship between the short pulse stress test time and cumulative rate of defective bits;

FIG. 2 is a block diagram showing the configuration of a semiconductor storage device according to a preferred embodiment of the present invention;

FIG. 3 is a block diagram showing the main part of the semiconductor storage device of FIG. 2;

FIG. 4 is a flowchart illustrating the procedures for processing a short pulse stress test according to the present invention;

FIG. 5(a) is a chart showing data in the deletion state before application of a pulse voltage; and

FIG. 5(b) is a chart showing data in the test completion state after application of the pulse voltage.

### DESCRIPTION OF THE PREFERRED EMBODIMENTS

The inventor of the present invention has found that by conducting a short pulse disturb stress test (hereafter, referred to as the “SPD stress test”) on a memory that has failed to operate normally, it is possible to identify memory cells in which data disturbance would occur and memory cells in which data disturbance would not occur. The present inventor thus proposes the present invention based on this new finding. In the SPD stress test, voltage having a shorter pulse width than that used in a conventional disturb test (the pulse having substantially the same time width as the read time) is applied to memory cells.

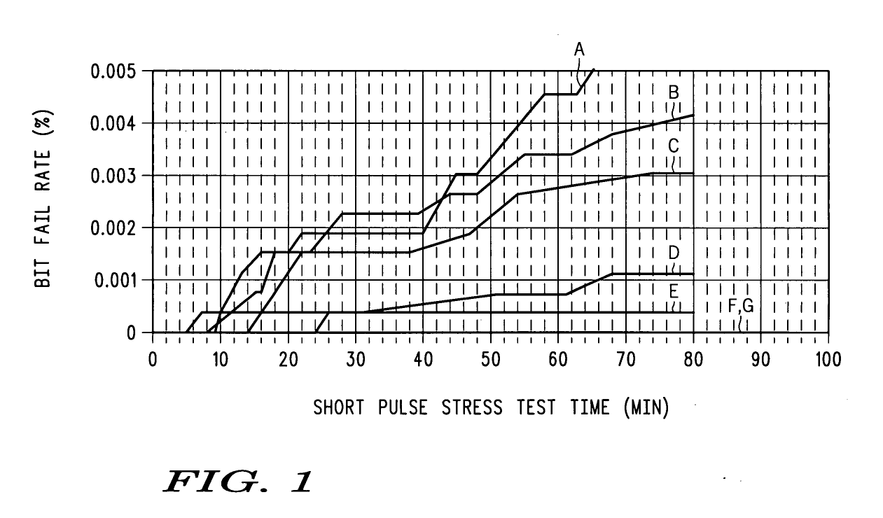

FIG. 1 shows a relationship between the time during which the SPD stress test was conducted and a cumulative rate of defective bits which have been proved defective due to change of data. The result of FIG. 1 was obtained by conducting the SPD stress test using five defective semiconductor storage devices A to E and two non-defective storage devices F and G. In tests other than the SPD stress test, significant differences between the group of the semiconductor storage devices A to E and the group of the semiconductor storage devices F and G could not be found. However, when conducting the SPD stress test the cumulative defective bit rate increased for semiconductor storage devices A to E, as shown FIG. 1. In the semiconductor storage devices F and G, the cumulative defective bit rate was remained null during the SPD stress test. Accordingly, it was found that defective products could be found by conducting the SPD stress test.

Further, the present inventor has also found that during the SPD stress test, if the voltage applied to the gate terminal of a memory cell is higher than the voltage used to read data from the memory cell, data disturbance would change the data of a memory cell at an early stage.

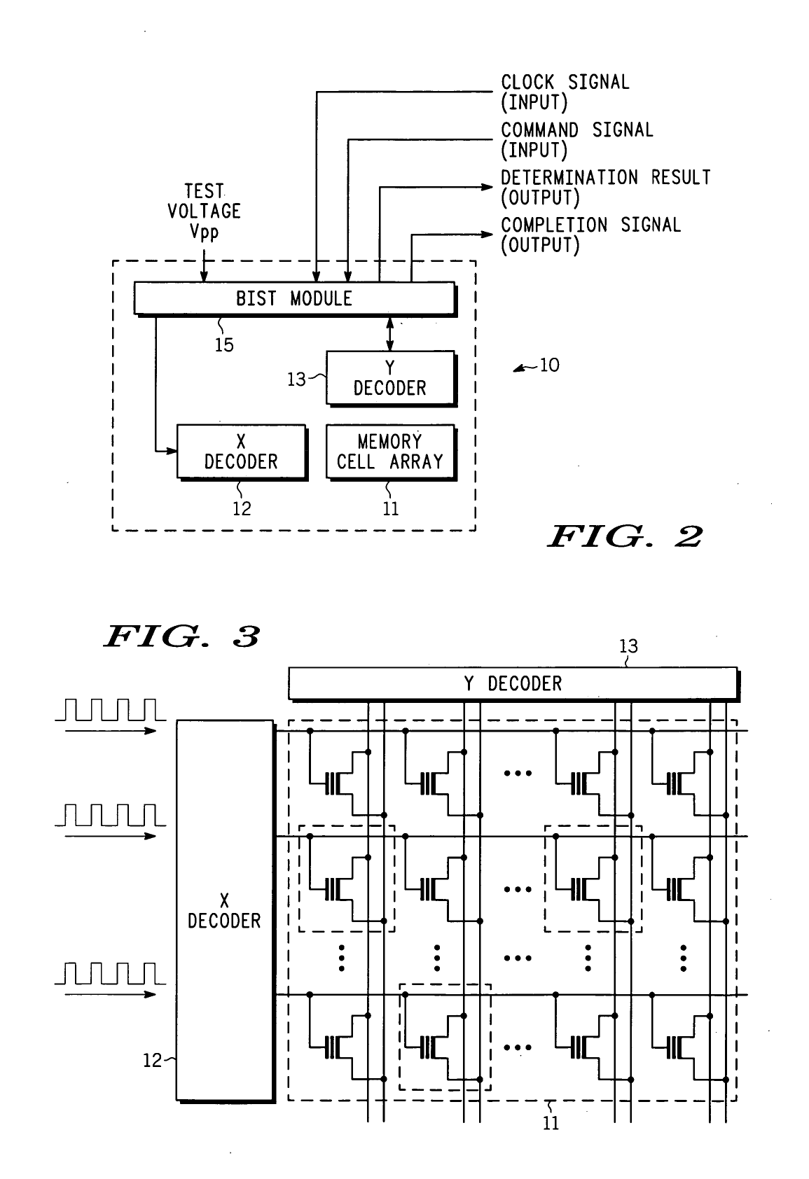

A preferred embodiment of the present invention will now be described with reference to FIGS. 2 to 5.

A semiconductor storage device according to a preferred embodiment of the present invention includes a chip incorporating a non-volatile memory. More specifically, as shown in FIGS. 2 and 3, the semiconductor storage device 10 of the preferred embodiment includes a-memory cell array 11, an X decoder 12, and a Y decoder 13. The memory cell array 11 includes a matrix of memory cells 21, as shown in FIG. 3. In this embodiment, each memory cell 21 is a NOR type flash memory. In each row, the gate terminals of the memory cells 21 are connected to a single line, with each line being controlled by the X decoder 12. In each column, the source terminals and the drain terminals of the memory cells 21 are connected to their respective lines, with each line being controlled by the Y decoder 13.

The X decoder 12 selects the line to which the gate terminal of the memory cell 21 that is to undergo data reading and writing is connected. Then, the X decoder 12 applies a predetermined voltage on the selected line. The Y decoder 13 selects the line to which the source terminal and the drain terminal of the memory cell 21 that is to undergo data reading and writing are connected. Then, the Y decoder 13 applies a predetermined voltage on the selected line.

The semiconductor storage device 10 of the preferred embodiment incorporates a built-in self test (BIST) module 15 for giving instructions to the X decoder 12 and the Y decoder 13. The BIST module 15, which functions as a test conducting means, outputs a signal to the X decoder 12 and the Y decoder 13 in response to a command signal provided from an external device to control the voltage applied to the memory cell 21, the period during which the voltage is applied, and the timing for applying the voltage. The BIST module 15 is supplied with test voltage Vpp from a voltage generation circuit (not shown) configured in the semiconductor storage device 10. The test voltage Vpp used in the preferred embodiment is about two times greater than the voltage used for writing data to or reading data from the memory cell 21 (e.g., 10 V).

The BIST module 15 is also provided with a clock signal and a command signal, which represents operation instructions, from a control circuit (not shown). The BIST module 15 determines the timing for applying voltage to a memory cells 21 via the X decoder 12 and the Y decoder 13 based on the received clock signal. Further, the BIST module 15 is set to perform various processes in association with each command signal. For example, the BIST module 15 writes data when receiving a command signal of “00” and deletes data when receiving a command signal of “01”. The BIST module 15 sends to the control circuit a signal representing determination result data of the test and a completion signal indicating that the test has been completed.

A program for executing the SPD stress test of the present invention is stored in the BIST module 15. In the preferred embodiment, the program has the BIST module 15 sequentially perform three processes to determine whether data in the memory cell is inverted so as to cause disturbance. When the program is started, the BIST module 15 receives from the control circuit a command signal instructing the execution of the SPD stress test.

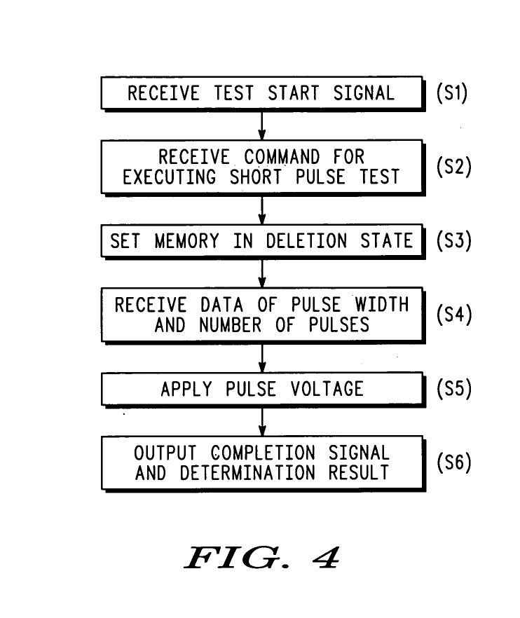

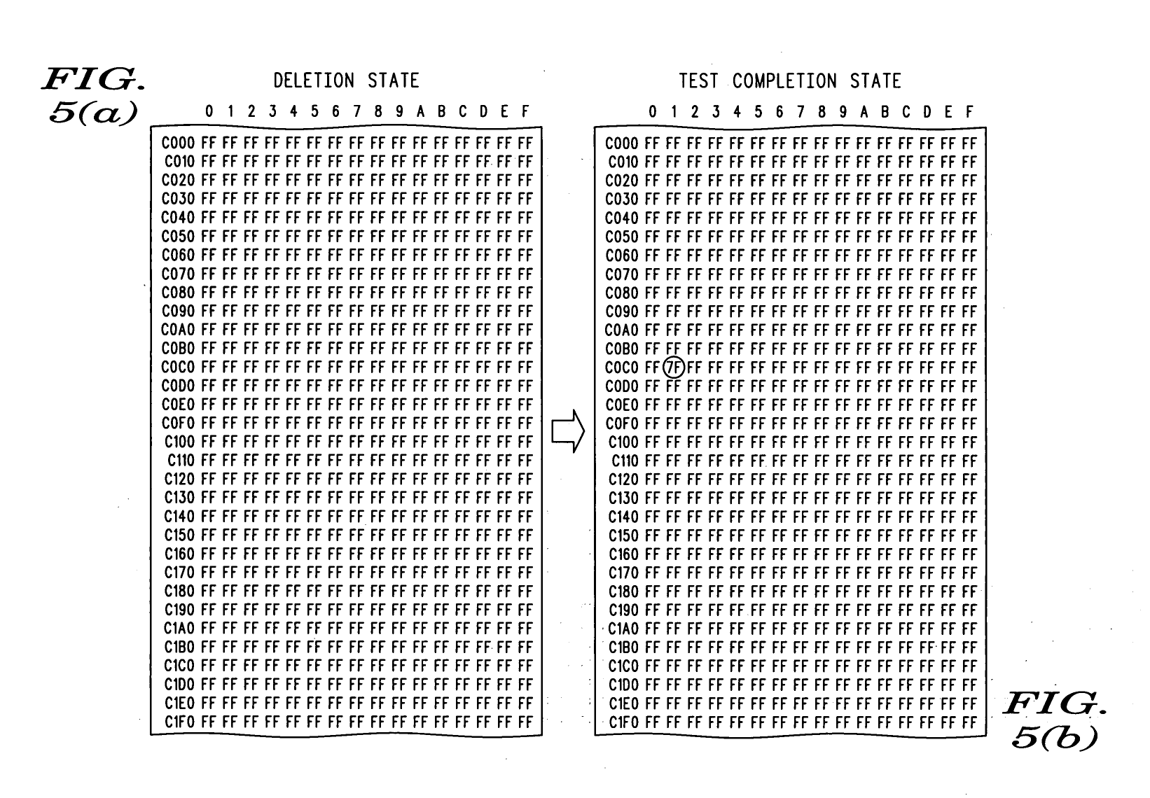

The procedures for executing the SPD stress test of the present invention will now be described with reference to FIGS. 4 and 5. In the preferred embodiment, the SPD stress test is performed during a burn-in test.

The semiconductor storage device 10 is placed in an environment in which the temperature is 125° C. and high. When receiving a test start signal from the control circuit (not shown) (step S1), the BIST module 15 of the semiconductor storage device 10 performs a known disturb test. In the known disturb test, for example, a predetermined voltage is continuously applied to the gate terminal, the source terminal, and the drain terminal of a memory cell 21.

When receiving from the control circuit a command signal for executing the SPD stress test (step S2), the BIST module 15 performs processing in accordance with the stored program.

The BIST module 15 sets each memory cell 21 in the memory cell array 11 in a deletion state (step S3). More specifically, the BIST module 15 provides the X decoder 12 and the Y decoder 13 with a signal that sets each memory cell 21 in a deletion state in which the data is “1”. FIG. 5(a) shows data at addresses “C000” to “C1FF” when every one of the memory cells 21 is in the deletion state. Each address represents two bytes of “FF” (“11111111” when shown as a binary (bit) code).

Following the command signal for execution of the SPD stress test, the BIST module 15 receives from the control circuit data relating to the pulse width, voltage amplitude, and pulse number (voltage application time) of the SPD stress test (step S4). In the present embodiment, pulse voltage that alternately repeats an “L” level (0 V) and an “H” level (Vpp) at intervals of several microseconds is used. The application time of the pulse voltage is, for example, about two hours.

The BIST module 15 uses the input clock signal and test voltage Vpp to generate pulse voltage in accordance with the received data. The BIST module 15 then supplies the generated pulse voltage to the X decoder 12 so as to apply the generated pulse voltage to the gate terminal of each memory cell 21 at substantially the same timing (step S5). The BIST module 15 controls the Y decoder 13 so as to set the voltage at the source terminal and drain terminal of each memory cell 21 at 0 V.

The BIST module 15 then counts the pulse number and monitors the pulses for a predetermined time period (e.g., about two hours). When the predetermined time elapses from when the SPD stress test is started, the BIST module 15 outputs a completion signal and a determination result (step S6).

FIG. 5(b) shows a determination result after the SPD stress test has been conducted. The data at address C0C2 has changed to “7F” (“01111111” when shown as a binary (bit) code). Specifically, the data has changed from “11111111” to “01111111”. This indicates that the data in the memory cell 21 recording the uppermost bit of the address C0C2 has changed and suggests that this memory cell 21 may cause data disturbance.

As described above, when the SPD stress test is conducted by applying to the gate terminal of each memory cell 21 voltage that is higher than the voltage used for reading data from the memory cells 21, the data in a data memory cell 21 that may cause data disturbance would change at an early stage. Therefore, in the SPD stress test, a memory cell 21 in which data disturbance may occur is determined at an early stage by applying voltage that is higher than the voltage used for reading data to the gate terminals of the memory cells 21.

The present embodiment has the advantages described below.

In the present embodiment, pulse voltage having pulse widths for durations equal to or close to the time for reading data stored in the memory cells 21 is applied continuously to the gate terminal of each memory cell 21 at the same time. The continuous application of the pulse voltage for a predetermined time changes data of memory cells 21 in which data disturbance may occur. Thus, such data change is used to locate defective memory cells 21. Therefore, memory cells that may cause data disturbance are efficiently determined, and defective products may thus be efficiently eliminated.

In the SPD stress test of the preferred embodiment, pulse voltage that is higher than the voltage used for reading data from the memory cells 21 is applied. Therefore, data of a memory cell 21 that may cause failure changes at an early stage. This makes it possible to determine at an early stage whether the semiconductor storage device 10 includes a memory cell 21 that would cause disturbance.

In the SPD stress test of the preferred embodiment, prior to the application of pulse voltage to the gate terminals of the memory cells 21, “1” is written to each of the memory cells 21 so that the data at each address is “FF” as shown in FIG. 5(a). This enables efficient determination of whether a change has occurred in memory cell 21 by locating an address at which the data has changed from “FF” after the application of the pulse voltage.

It should be apparent to those skilled in the art that the present invention may be embodied in many other specific forms without departing from the spirit or scope of the invention. Particularly, it should be understood that the present invention may be embodied in the following forms.

In the preferred embodiment, the application of pulse voltage is performed for about two hours during the SPD stress test. However, the present invention is not limited in such a manner, and the time for applying the pulse voltage may be shorter as apparent from FIG. 1.

In the preferred embodiment, the application of pulse voltage is performed in a deletion state in which the data is set to “1” to determine whether a memory cell 21 will cause disturbance if the data changes. The present invention is not limited in this manner. However, data of “0” may be written instead. In this case, pulse voltage is applied so as to determine whether a memory cell 21 will cause disturbance based on whether the data of the memory cell 21 changes.

In the preferred embodiment, the semiconductor storage device 10 that undergoes the SPD stress test is an NOR type flash memory. However, the SPD stress test may also be conducted on other types of semiconductor storage devices including memory cells 21 that may cause disturbance. Depending on the type of the semiconductor storage device 10, the possibility of disturbance occurring may be determined by applying pulse voltage to the source terminals or the drain terminals instead of the gate terminals of the memory cells 21.

In the preferred embodiment, the pulse voltage, which is generated by the BIST circuit incorporated in the semiconductor storage device 10, is applied to the gate terminals of the memory cells 21. However, the present invention is not limited in this manner. For example, a signal may be provided to the X decoder 12 and the Y decoder 13 from a test circuit that is not incorporated in the semiconductor storage device 10 (built-out stress test circuit, or BOST circuit) to perform a similar SPD stress test. Further, the test circuit does not have to be used to conduct a disturb test. For example, pulse voltage may be applied by a control circuit (computer) to the memory cells 21 to conduct a disturb test without using a test circuit. In this case, the control circuit executes a test program and functions as a means for applying a pulse-shaped voltage having a duration equivalent to the read time of the memory cells, a means for comparing data after the application of the pulse voltage with the initial data in the memory cells, and a means for locating memory cells that will cause disturbance.

The present examples and embodiments are to be considered as illustrative and not restrictive, and the invention is not to be limited to the details given herein, but may be modified within the scope and equivalence of the appended claims.

1. A method for testing a semiconductor storage device including a plurality of memory cells, the method comprising the steps of:
applying to predetermined terminals of the memory cells a pulse voltage, which has a duration equal to or close to a data read time of the memory cells, at the same time for a predetermined time period;
reading data from the memory cells after the application of the pulse voltage to compare the read data with initial data of the memory cells before the application of the pulse voltage; and
determining a memory cell in which the initial data before the application of the pulse voltage differs from the read data after the application of the pulse voltage as being a memory cell that would cause disturbance.

2. The test method for a semiconductor storage device according to claim 1, further comprising the step of:
writing data that is the same in each of the memory cells as the initial data before the application of the pulse voltage.

3. The test method for a semiconductor storage device according to claim 1, wherein a voltage higher than a voltage used to read data from the memory cells is used as the pulse voltage applied to the predetermined terminals of the memory cells.

4. A test program for testing a semiconductor storage device including a plurality of memory cells, the test program comprising the steps of:
applying to predetermined terminals of the memory cells a pulse voltage, which has a duration equal to or close to a data read time of the memory cells, at the same time for a predetermined time period;
reading data from the memory cells after the application of the pulse voltage to compare the read data with initial data of the memory cells before the application of the pulse voltage; and
determining a memory cell in which the data before the application of the pulse voltage differs from the read data after the application of the pulse voltage as being a memory cell that would cause disturbance.

5. A semiconductor storage device including a plurality of memory cells, the semiconductor device comprising:
a test executing means for supplying voltage and providing a signal to the memory cells to perform an operation check on the memory cells, wherein the test executing means selects terminals of the memory cells to which the voltage is to be applied and applies to the selected terminals a pulse voltage, which has a duration equal to or close to a data read time of the memory cells, at the same time for a predetermined time period.

6. The semiconductor storage device according to claim 5, wherein the test executing means applies to the terminals of the memory cells a voltage that is higher than the voltage used to read data from the memory cells.

7. The semiconductor storage device according to claim 5, wherein the test executing means is a built-in self test circuit incorporated in the storage device to execute a test.
